(19) United States
(12) Patent Application Publication
(10) Pub. No.: US 2014/0091288 A1
(43) Pub. Date: Apr. 3, 2014

(54) ORGANIC LIGHT EMITTING DIODE DISPLAY AND METHOD OF MANUFACTURING THE SAME

(71) Applicant: Samsung Display Co., Ltd., Yongin-City (KR)

(72) Inventors: Keun-Soo Lee, Yongin-City (KR); Seong-Jun Lee, Yongin-City (KR); Young-Gu Kim, Yongin-City (KR); Jung-Ju Yu, Yongin-City (KR); Yun Jeong, Yongin-City (KR); Hyo-Young Mun, Yongin-City (KR); Ha-Gyeong Song, Yongin-City (KR); Hyun-Jun Cho, Yongin-City (KR); Young-Ji Kim, Yongin-City (KR); Dong-Un Jin, Yongin-City (KR)

(21) Appl. No.: 14/030,600

(22) Filed: Sep. 18, 2013

(30) Foreign Application Priority Data
Sep. 28, 2012 (KR) 10-2012-0109448
Aug. 1, 2013 (KR) 10-2013-0091610

(51) Int. Cl. H01L 51/52

(52) U.S. Cl. CPC H01L 51/5256
USPC 257/40

(57) ABSTRACT

An organic light emitting diode (OLED) display includes a display panel including a flexible substrate and a thin film encapsulation (TFE) for covering and protecting an organic light emitting element formed on the flexible substrate, a first protective film arranged on the TFE to be opposite to the TFE, a second protective film arranged on the flexible substrate to be opposite to the flexible substrate, a first adhesive disposed between the TFE and the first protective film, a second adhesive disposed between the flexible substrate and the second protective film, a third protective film arranged on the second protective film to be opposite to the second protective film, and a third adhesive disposed between the second protective film and the third protective film.

### CLAIM OF PRIORITY

This application makes reference to, incorporates the same herein, and claims all benefits accruing under 35 U.S.C. §119 from Korean Patent Application No. 10-2012-0109448 filed in the Korean Intellectual Property Office on Sep. 28, 2012, and Korean Patent Application No. 10-2013-0091610 filed on Aug. 1, 2013.

### BACKGROUND OF THE INVENTION

1. Field of the Invention

The present invention generally relates to an organic light emitting diode (OLED) display and a method of manufacturing the same, and more particularly, to an organic light emitting diode (OLED) display having a structure in which a bending phenomenon is relieved and a method of manufacturing the same.

2. Description of the Related Art

An organic light emitting diode (OLED) display includes organic light emitting elements that include hole injection electrodes, organic emission layers, and electron injection electrodes. Each organic light emitting element emits light by energy generated when exciton generated in an organic emission layer by combination of electrons and holes is transited from an exited state to a ground state and the organic light emitting diode (OLED) display displays a predetermined image using such light emitting.

Since the organic light emitting diode (OLED) display has a self-light emitting (self-luminance) characteristic and does not need additional light source unlike a liquid crystal display (LCD), the thickness and weight of the organic light emitting diode (OLED) display may be reduced. In addition, since the organic light emitting diode (OLED) display has a high quality characteristic such as low power consumption, high luminance, and high response speed, the organic light emitting diode (OLED) display is spotlighted as the next generation display device.

On the other hand, the organic light emitting diode (OLED) display has a panel structure in which a driving circuit unit and the organic light emitting element formed on a flexible substrate are protected by a thin film encapsulation (TFE). In a process of forming the TFE, chemical vapor deposition (CVD) is used so that a flexible panel is strongly stressed by the strong compress characteristic of SiNₓ and that the panel is bent. In addition, due to the bending characteristic (flexibility) of a flexible material, when the force (tension or compress force) of the layers that form the inside is not balanced, curl bent in one direction is generated. Although a thick bottom film is attached to the bottom of the panel, a bending phenomenon is generated. Therefore, it is difficult to perform a vacuum absorption process, an align key recognition process, a transport process, and a load process for performing a subsequent process.

The above information disclosed in this Background section is only for enhancement of understanding of the background of the invention and therefore it may contain information that does not form the prior art that is already known in this country to a person of ordinary skill in the art.

### SUMMARY OF THE INVENTION

In order to solve the above problem, in the embodiments of the present invention, an organic light emitting diode (OLED) display in which the bottom protective layer of a display panel is formed of a two-layer film is provided.

In addition, a method of manufacturing the organic light emitting diode (OLED) display in which reverse curl is applied to the bottom protective layer in an opposite direction to the bending direction of the display panel when the display device is manufactured so that the bottom protective layer is attached to the display panel and that the bending phenomenon of the display device is relieved is provided.

An organic light emitting diode (OLED) display device constructed asn an embodiment according to the principles of the present invention includes a display panel including a flexible substrate and a thin film encapsulation (TFE) for covering and protecting an organic light emitting element formed on the flexible substrate, a first protective film arranged on the TFE to be opposite to the TFE, a second protective film arranged on the flexible substrate to be opposite to the flexible substrate, a first adhesive disposed between the TFE and the first protective film, a second adhesive disposed between the flexible substrate and the second protective film, a third protective film arranged on the second protective film to be opposite to the second protective film, and a third adhesive disposed between the second protective film and the third protective film.

The second adhesive and the third adhesive may have the same property.

The first to third protective films may have the same property.

The first adhesive may have a thickness of about 70 μm to 80 μm.

The second adhesive and the third adhesive may have a thickness of 20 μm to 30 μm.

The flexible substrate may be formed of a plastic material.

The first to third protective films may be formed of a flexible plastic material.

The first protective film may have a thickness of 70 μm to 80 μm.

The second protective film and the third protective film may have a thickness of 20 μm to 30 μm.

An organic light emitting diode (OLED) display according to the present invention further includes a fourth protective film arranged on the first protective film to be opposite to the first protective film and a fourth adhesive disposed between the first protective film and the fourth protective film and the first adhesive and the fourth adhesive may have the same property.

The fourth protective film may have the same property as the first to third protective films.

The fourth adhesive may have a thickness of about 5 μm to 15 μm.

The fourth protective film may be formed of a flexible plastic material.

The fourth protective film may have a thickness of about 20 μm to 30 μm.

A total thickness of the second adhesive, the second protective film, the third adhesive, and the third protective film may be about 90 μm to 110 μm.

The second protective film may have a thickness of about 45 μm to 50 μm and the third protective film may have a thickness of about 20 μm to 30 μm.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a cross-sectional view schematically illustrating an organic light emitting diode (OLED) display constructed as an embodiment according to the principles of the present invention;

FIG. 2 is a cross-sectional view schematically illustrating that a top protective layer and a display panel of the organic light emitting diode (OLED) display according to an embodiment of the present invention are bent in a downwardly convex shape;

FIG. 3 is a cross-sectional view schematically illustrating that reverse curl is applied to a bottom protective layer of the organic light emitting diode (OLED) display according to an embodiment of the present invention in an upwardly convex shape;

FIG. 4 is a flowchart illustrating a method of manufacturing an organic light emitting diode (OLED) display according to an embodiment of the present invention;

FIGS. 5A to 5G are process cross-sectional views illustrating the method of manufacturing the organic light emitting diode (OLED) display according to an embodiment of the present invention.

FIG. 6 is a graph measuring and illustrating the heights of the curl of the display device when the bottom protective layer of the organic light emitting diode (OLED) display according to an embodiment of the present invention is a single-layer film and when the bottom protective layer of the organic light emitting diode (OLED) display according to an embodiment of the present invention is a two-layer film.

FIG. 7 is a graph measuring and illustrating the heights of the curl of the bottom protective layer of the organic light emitting diode (OLED) display according to an embodiment of the present invention when the curl is not formed, when the curl is formed in the single-layer bottom protective layer, and when the curl is formed in the two-layer bottom protective layer;

FIG. 8 is a graph measuring and illustrating the heights of the curl of the display device with the bottom protective layer attached to a display panel when the curl is not formed in the bottom protective layer of the organic light emitting diode (OLED) display according to an embodiment of the present invention, when the curl is formed in the single-layer bottom protective layer, and when the curl is formed in the two-layer bottom protective layer;

FIG. 9 is a graph measuring and illustrating the heights of the curl of a mother substrate when the bottom protective layer of the OLED display according to an embodiment of the present invention is attached to a mother substrate in accordance with thicknesses of the film that forms the bottom protective layer, whether the film is a single-layer film or a two-layer film, and whether the film is a symmetric film or an asymmetric film; and

FIG. 10 is a graph measuring and illustrating the heights of the curl of a display device when the bottom protective layer of the OLED display according to an embodiment of the present invention is attached to the display device in accordance with thicknesses of the film that forms the bottom protective layer, whether the film is a single-layer film or a two-layer film, and whether the film is a symmetric film or an asymmetric film.

### DETAILED DESCRIPTION OF THE INVENTION

Hereinafter, exemplary embodiments of the present invention will be described in detail with reference to the accompanying drawings so that a person of ordinary skill in the art may easily perform the present invention. The present invention may be realized in various forms and is not limited to the exemplary embodiments described hereinafter.

In addition, in various exemplary embodiments, the same constituent elements are denoted by the same reference numerals and are representatively described in an exemplary embodiment and different elements from the elements of an exemplary embodiment will be described in other exemplary embodiments.

The drawings are schematic and are not illustrated in accordance with a scale. The relative sizes and ratios of the parts in the drawings are exaggerated or reduced for clarity and convenience in the drawings and an arbitrary size is only exemplary and is not limited. The same structures, elements, or parts illustrated in no less than two drawings are denoted by the same reference numerals in order to represent similar characteristics. When a part is referred to as being “on” another part, it can be directly on the other part or intervening parts may also be present.

An exemplary embodiment of the present invention is illustrated in detail. As a result, various modifications are expected to be made. Therefore, the exemplary embodiment is not limited to a specific shape of an illustrated region but, for example, includes a change in the shape in accordance with manufacturing.

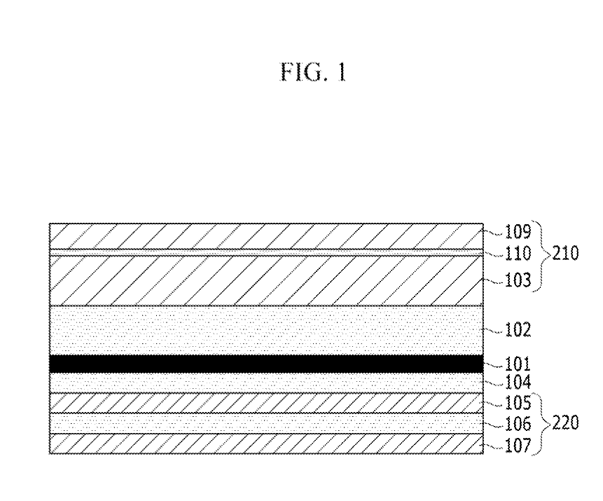

Hereinafter, referring to FIGS. 1 to 3, an organic light emitting diode (OLED) display constructed as an embodiment according to the principles of the present invention will be described.

FIG. 1 is a cross-sectional view schematically illustrating an organic light emitting diode (OLED) display according to an embodiment of the present invention. Referring to FIG. 1, the organic light emitting diode (OLED) display includes a display panel 101, a first protective film 103, a second protective film 105, a first adhesive 102, a second adhesive 104, a third protective film 107, and a third adhesive 106. In addition, a fourth adhesive 110 and a fourth protective film 109 may be included on the first protective film 103. A structure in which the first protective film 103 and the fourth protective film 109 are attached to each other by the fourth adhesive 110 may be defined as a top protective layer 210 for convenience sake. A structure in which the second protective film 105 and the third protective film 107 are attached to each other by the third adhesive 106 may be defined as a bottom protective layer 220 for convenience sake. At this time, based on the display panel 101, the protective layer on the side of a thin film encapsulation (TFE) that forms the display panel 101 may be defined as the top protective layer 210 and the protective layer attached to a flexible substrate that forms the display panel 101 may be defined as the bottom protective layer 220.

The display panel 101 may include a driving circuit unit and an organic light emitting element formed on the flexible substrate and the thin film encapsulation (TFE). The flexible substrate may be formed of a flexible plastic material. However, the present invention is not limited to the above and the flexible substrate may be formed of a metal substrate made of stainless steel and various flexible materials. The flexible substrate may be formed of a plastic material having excellent heat resistance and durability such as polyethylene ether phthalate, polyethylene naphthalene, polycarbonate, polyarylate, polyetherimide, polyether sulfone, and polyimide.

The driving circuit unit includes a thin film transistor and drives the organic light emitting element. The organic light emitting element is connected to the driving circuit unit and emits light in accordance with a driving signal received from the driving circuit unit to display an image. The organic light emitting element and the driving circuit unit may have various structures in a range where modifications may be easily made by a person of ordinary skill in the art.

The TFE is formed on the flexible substrate of the display panel to cover and protect the organic light emitting element and the driving circuit unit and may be formed by alternately laminating one or more organic layers and one or more inorganic layers with each other. The inorganic layers and the organic layers may be plural, respectively.

The organic layers are formed of polymers and may be a single layer or a laminated layer formed of one of polyethylene terephthalate (PET), polyimide, polycarbonate, epoxy, polyethylene, and polyacrylate. The organic layers may be formed of polyacrylate and, in detail, include polymerized monomer composition including diacrylate-based monomer and triacrylate-based monomer. Monoacrylate-based monomer may be further included in the monomer composition. In addition, a already known photoinitiator such as TPO (2,4,6-trimethylbenzoyl diphenyl phosphoine) may be further included in the monomer composition. However, the present invention is not limited to the above.

The inorganic layers may be single layers or laminated layers including a metal oxide or a metal nitride. In detail, the inorganic layers may include one of SiNₓ, Al₂O₃, SiO₂, and TiO₂.

The uppermost layer exposed the outside among the layers that form the TFE may be formed of the inorganic layer in order to prevent moisture from permeating into the organic light emitting diode (OLED).

The TFE may include at least one sandwich structure in which at least one organic layer is inserted between at least two inorganic layers. In addition, the TFE may include at least one sandwich structure in which at least one inorganic layer is inserted between at least two organic layers.

The TFE may sequentially include a first inorganic layer, a first organic layer, and a second inorganic layer from the top of an OLED layer. In addition, the TFE may sequentially include a first inorganic layer, a first organic layer, a second inorganic layer, a second organic layer, and a third inorganic layer from the top of the OLED layer. In addition, the TFE may sequentially include a first inorganic layer, a first organic layer, a second inorganic layer, a second organic layer, a third inorganic layer, a third organic layer, and a fourth inorganic layer from the top of the OLED layer.

A halogen metal layer including lithium fluoride (LiF) may be further included between the OLED layer and the first inorganic layer. The halogen metal layer may prevent the OLED layer from being damaged when the first inorganic layer is formed of a sputtering method or a plasma deposition method.

The first organic layer may be formed to have a smaller area than that of the second inorganic layer and the second organic layer may be formed to have a smaller area than that of the third inorganic layer. In addition, the first organic layer may be formed to be completely covered with the second inorganic layer and the second organic layer may be formed to be completely covered with the third inorganic layer.

The first protective film 103 is arranged to be opposite to the TFE of the display panel 101 and the first adhesive 102 is disposed between the TFE and the first protective film 103 so that the first protective film 103 is attached to the TFE of the display panel 101 through the first adhesive 102.

The second protective film 105 is arranged to be opposite to the flexible substrate of the display panel 101 and the second adhesive 104 is disposed between the flexible substrate of the display panel 101 and the second protective film 105 so that the second protective film 105 is attached to the flexible substrate of the display panel 101 through the second adhesive 104.

The third protective film 107 is arranged to be opposite to the second protective film 105 and the third adhesive 106 is disposed between the second protective film 105 and the third protective film 107 so that the third protective film 107 is attached to the second protective film 105 through the third adhesive 106.

At this time, the first to third protective films 103 to 107 may have the same property and may improve the strength of the display panel 101 and prevent the display panel 101 from being damaged. The first to third protective films 103 to 107 may be formed of a plastic material and may have a flexible characteristic like the flexible substrate of the display panel 101. The first to third protective films 103 to 107 may be common films formed of materials such as polyethylene (PE), polycarbonate, polyethylene terephthalate (PET), urethane, and polyethylene naphthalate (PEN). Other than the above, various kinds of films already known in the art may be used.

On the other hand, the first protective film 103 may have a thickness of about 70 μm to 80 μm and the second protective film 105 and the third protective film 107 may have a thickness of about 20 μm to 30 μm.

In addition, in an organic light emitting diode (OLED) display according to another embodiment of the present invention, the fourth protective film 109 may be arranged on the first protective film 103 to be opposite to the first protective film 103 and the fourth adhesive 110 may be disposed between the first protective film 103 and the fourth protective film 109. That is, the fourth protective film 109 may be attached to the first protective film 103 through the fourth adhesive 110. The fourth protective film 109 may have the same property as the first to third protective films 103 to 107 and may be formed of a flexible plastic material to improve the strength of the display panel 101 and to prevent the display panel 101 from being damaged. The fourth protective film 109 may be a film formed of the same material as the first to third protective films 103 to 107.

The fourth protective film 109 may have a thickness of about 20 μm to 30 μm.

On the other hand, at least one of the first to fourth protective films 103 to 109 may be a polarizing film having a polarizing function. Among the first to fourth protective films 103 to 109, the protective film having the polarizing function may be formed of a material having a similar property to the properties of the other protective films.

On the other hand, the second adhesive 104 and the third adhesive 106 may have the same property. In addition, the fourth adhesive 110 may have the same property as the first adhesive 102. The first to fourth adhesives 102 to 110 may be softer than the first to fourth protective films 103 to 109, the flexible substrate of the display panel 101, and the TFE. Various kinds of adhesives already known in the art may be used as the first to fourth adhesives 102 to 110.

On the other hand, the first adhesive 102 may have a thickness of about 70 μm to 80 μm, the second adhesive 104 and the third adhesive 106 may each have a thickness of about 20 μm to 30 μm, and the fourth adhesive 110 may have a thickness of about 5 μm to 15 μm.

On the other hand, the total thickness of the attachment structure of the bottom protective layer 220 and the second adhesive 104 may be about 100 μm. That is, the total thickness obtained by adding the thickness of the second adhesive 104, the thickness of the second protective film 105, the thickness of the third adhesive 106, and the thickness of the third protective film 107 may be about 90 μm to 110 μm. In addition, the thickness of the second protective film 105 may be about 45 μm to 50 μm and the thickness of the third protective film 107 may be about 20 μm to 30 μm. As described above, the total thickness of the attachment structure of the bottom protective layer 220 and the second adhesive 104 is maintained as about 100 μm and the attachment structure is formed of an asymmetric two-layer film structure so that bending phenomenon relieving effect may be remarkably improved.

In the embodiment of FIG. 1, the bottom protective layer 220 is formed of the two-layer film structure. However, the bottom protective layer 220 may be formed of a multi-layer film consisting of no less than two layers.

The above-described organic light emitting diode (OLED) display according to the embodiments of the present invention includes a two-layer bottom protective layer 220 having a structure in which the second protective film 105 and the third protective film 107 are laminated. In order to prevent the display device from being bent due to a phenomenon in which both ends of the display panel 101 are bent upward or downward by strong stress applied to the display panel 101 after forming the TFE, the bottom protective layer 220 is formed of a two-layer film and is attached to the display panel 101 with curl applied in an opposite direction to the bending direction of the display panel 101 so that the bending degree of the display panel 101 may be reduced and that the bending phenomenon may be relieved.

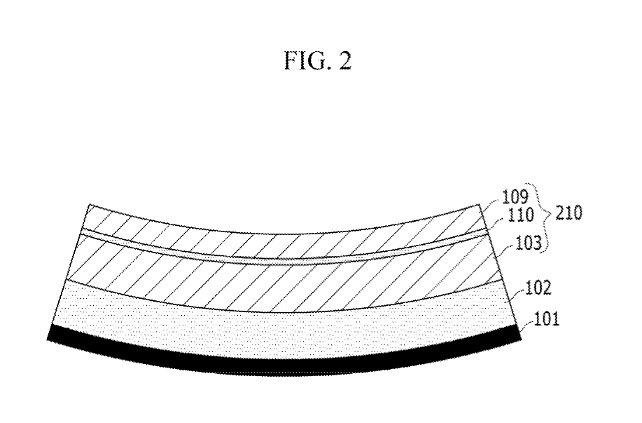

FIG. 2 is a cross-sectional view schematically illustrating that the top protective layer and the display panel of the organic light emitting diode (OLED) display according to an embodiment of the present invention are bent in a downwardly convex shape. Here, an example in which the top protective layer 210 has a structure in which, the first protective film 103, the fourth adhesive 110, and the fourth protective film 109 are laminated is illustrated. When the top protective layer 210 is attached after a process of forming the TFE of the display panel 101 by chemical vapor deposition (CVD), the thickness of SiNₓ deposited by CVD increases so that both ends of the display panel 101 are bent upward or downward due to the strong compress characteristic of SiNₓ. FIG. 2 illustrates that the top protective layer 210 and the display panel 101 are bent in the downwardly convex shape. However, the top protective film and the display panel 101 may be bent in an opposite direction, that is, in an upwardly convex shape.

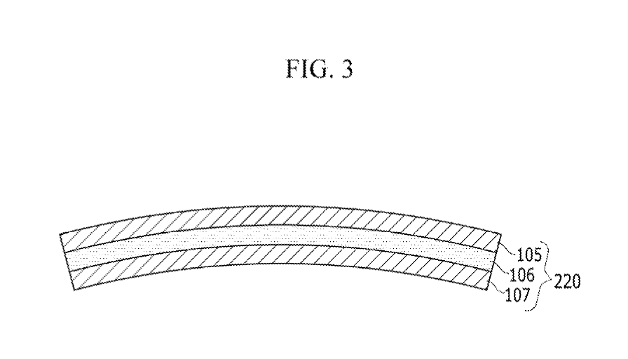

FIG. 3 is a cross-sectional view schematically illustrating that reverse curl is applied to the bottom protective layer of the organic light emitting diode (OLED) display according to an embodiment of the present invention in an upwardly convex shape. Here, the bottom protective layer 220 has a structure in which the second protective film 105, the third adhesive 106, and the third protective film 107 are laminated. Before the bottom protective layer 220 is attached to the display panel 101, curl is applied to the bottom protective layer 220 in an opposite direction to the direction in which the display panel 101 is bent. In order to form downwardly convex curl in the bottom protective layer 220, in the state where the second protective film 105 and the third protective film 107 are attached to each other, the bottom protective layer may be heated while applying compress force to the second protective film 105 and tension to the third protective film 107 at both ends thereof to be cooled. To the contrary, in order to form upwardly convex curl in the bottom protective layer 220, in the state where the second protective film 105 and the third protective film 107 are attached to each other, the bottom protective layer may be heated while applying tension to the second protective film 105 and compress force to the third protective film 107 at both ends thereof to be cooled.

On the other hand, in order to form the curl of the bottom protective layer 220, the second protective film 105 and the third protective film 107 are attached to each other by the third adhesive 106 with different tensions applied so that the upwardly or downwardly convex curl may be formed in the bottom protective layer 220. The method of applying curl to the bottom protective layer is not limited to the above and curl may be applied by various technologies already known in the art.

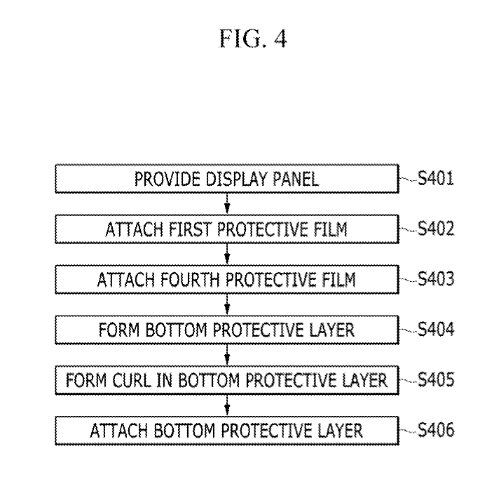

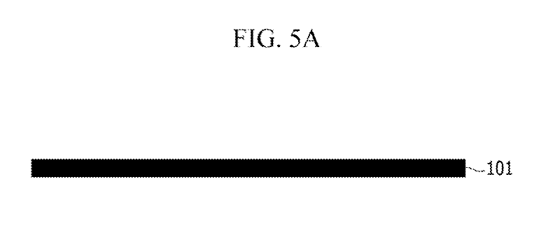

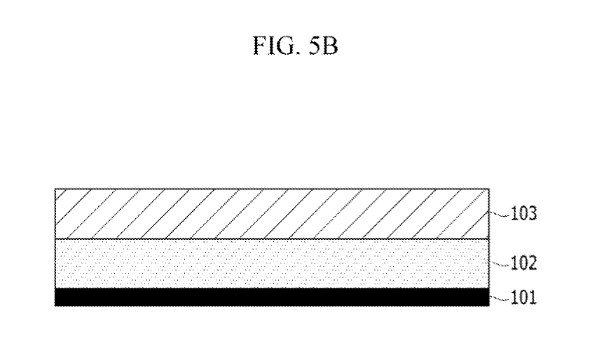

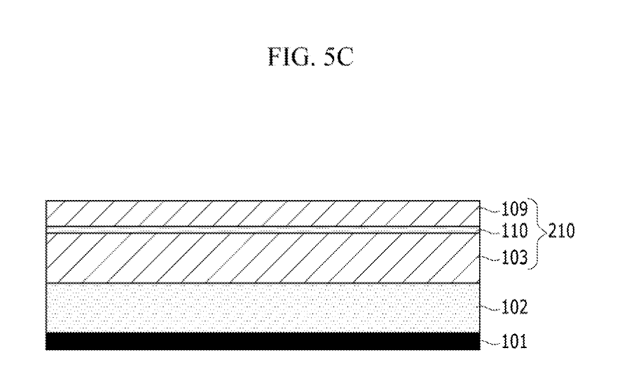

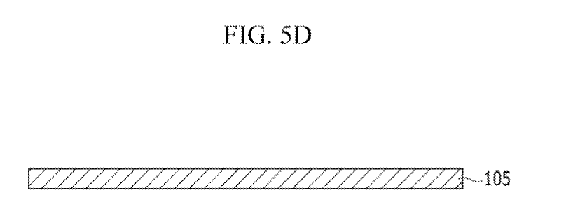

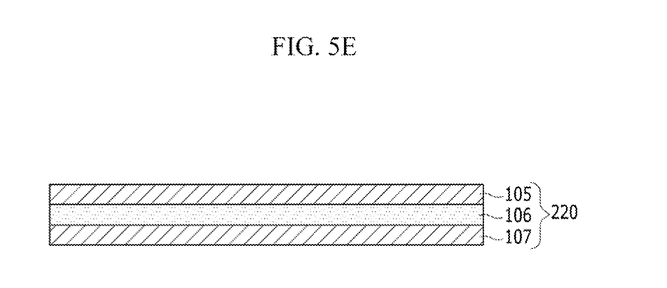

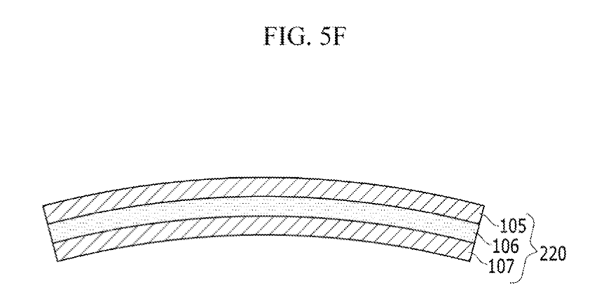

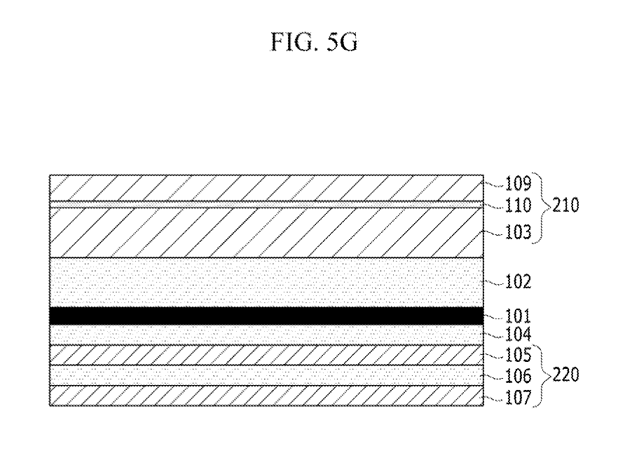

Hereinafter, referring to FIG. 4 and FIGS. 5A to 5G, a method of manufacturing the organic light emitting diode (OLED) display according to an embodiment of the present invention will be described.

FIG. 4 is a flowchart illustrating a method of manufacturing the organic light emitting diode (OLED) display according to an embodiment of the present invention. FIGS. 5A to 5G are process cross-sectional views illustrating the method of manufacturing the organic light emitting diode (OLED) display according to an embodiment of the present invention.

First, the display panel 101 in which the TFE is formed on the flexible substrate including the driving circuit unit and the organic light emitting element is provided (S401, FIG. 5A). The display panel 101 is completed by forming a barrier layer on the flexible substrate, by forming the driving circuit unit and the organic light emitting element on the bather layer, and by forming the TFE for covering and protecting the organic light emitting element and the driving circuit on the flexible substrate.

Next, the first protective film 103 is attached onto the TFE using the first adhesive 102 to be opposite to the TFE (S402, FIG. 5B).

Next, the third protective film 107 is attached onto the provided second protective film 105 using the third adhesive 106 to form the bottom protective layer 220 (S404, FIG. 5E).

Next, the bottom protective layer 220 is attached onto the flexible substrate using the second adhesive 104 so that the second protective film 105 is opposite to the flexible substrate of the display panel 101 (S406, FIG. 5G) to complete the organic light emitting diode (OLED) display.

Attaching the first protective film (S402, FIG. 5B), forming the bottom protective layer (S404, FIG. 5E), and attaching the bottom protective layer (S406, FIG. 5G) may be performed using a method of applying heat and pressure.

On the other hand, a method of manufacturing an organic light emitting diode (OLED) display according to another embodiment of the present invention may further include applying curl convex toward the second protective film 105 of the bottom protective layer 220 (S405, FIG. 5F) after forming the bottom protective layer (S404, FIG. 5E). At this time, in order to apply curl, the bottom protective layer 220 may be heated while applying tension to the second protective film 105 and compress force to the third protective film 107 at both ends thereof to be cooled.

To the contrary, a method of manufacturing an organic light emitting diode (OLED) display according to still another embodiment of the present invention may further include applying curl convex toward the third protective film 107 of the bottom protective layer 220 (S405, FIG. 5F) after forming the bottom protective layer (S404, FIG. 5E). At this time, in order to apply curl, the bottom protective layer 220 may be heated while applying compress force to the second protective film 105 and tension to the third protective film 107 at both ends thereof to be cooled.

The bottom protective layer 220 is heated with both ends thereof fixed and with pressure applied to the center of the second protective film 105 or the third protective film 107 to be cooled so that curl convex toward the second protective film 105 or the third protective film 107 may be applied.

The method of applying curl to the bottom protective layer 220 is not limited to the above and various methods already known in the art may be used.

On the other hand, in forming the bottom protective layer (S404), first tension is applied to the second protective film 105, second tension different from the first tension is applied to the third protective film 107, and the second protective film 105 and the third protective film 107 are attached to each other so that curl convex toward the second protective film 105 or the third protective film 107 may be applied.

On the other hand, a method of manufacturing an organic light emitting diode (OLED) display according to still another embodiment of the present invention may further include attaching the fourth protective film 109 onto the first protective film 103 using the fourth adhesive 110 (S403, FIG. 5C) after attaching the first protective film 103 onto the TFE using the first adhesive 102 (S402, FIG. 5B). Attaching the fourth protective film 109 may be performed using the method of applying heat and pressure like attaching the first protective film 103 (S402). Attaching the fourth protective film 109 (S403) may be performed not only after attaching the first protective film 103 (S402) but also after forming the bottom protective layer (S404), after forming curl (S405), or after attaching the bottom protective layer (S406).

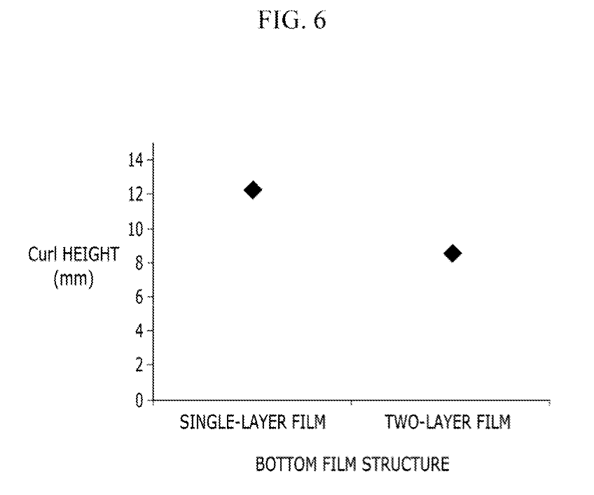

FIG. 6 is a graph measuring and illustrating the heights of the curl of the display device when the bottom protective layer of the organic light emitting diode (OLED) display according to an embodiment of the present invention is a single-layer film and when the bottom protective layer of the organic light emitting diode (OLED) display according to an embodiment of the present invention is the two-layer film.

Referring to FIG. 6, when the single-layer film is used as the bottom protective layer of the same thickness like in the conventional structure, it is confirmed that the height of the curl of the display device is about 11 mm to 13 mm. However, when the two-layer film according to an embodiment of the present invention is used, the height of the curl of the display device is confirmed to be about 7 mm to 9 mm. That is, when the bottom protective layer is formed of the two-layer film, it is noted that the bending phenomenon of the display device may be relieved. At this time, the height of the curl means a difference in the height of one end of a flat layer that is not bent and the height of one end of a bent layer in which curl is formed. The height of the curl has a positive value when the layer is bent upward and the height of the curl has a negative value when the layer is bent downward.

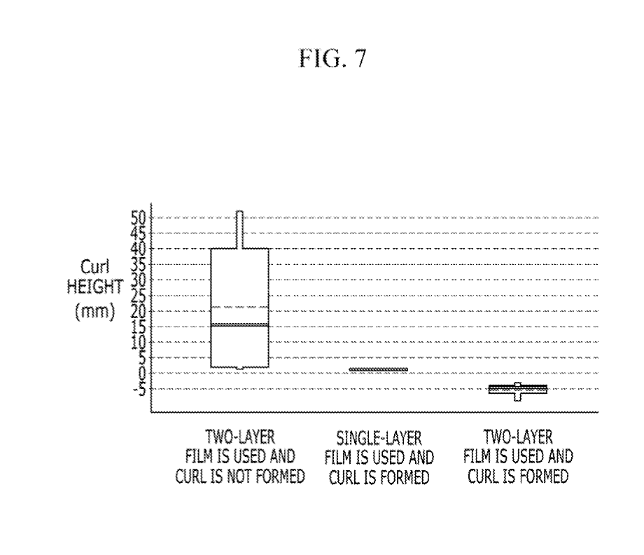

FIG. 7 is a graph measuring and illustrating the heights of the curl of the bottom protective layer of the organic light emitting diode (OLED) display according to an embodiment of the present invention when the curl is not formed, when the curl is formed in the single-layer bottom protective layer, and when the curl is formed in the two-layer bottom protective layer.

As illustrated in FIG. 7, when the bottom protective layer is formed of the two-layer film and curl is not applied, the height of the curl of the bottom protective layer is distributed in a range of about 2 mm to 53 mm, the average height of the curl is about 21.375 mm, and an intermediate value is about 15.5 mm. In addition, when the bottom protective layer is made single and curl is applied, the height of the curl of the bottom protective layer is distributed in a range of about 0.5 mm to 2 mm, the average height of the curl is about 1.125 mm, and an intermediate value is about 1 mm. In addition, when the bottom protective layer is formed of the two-layer film and curl is applied, the height of the curl is distributed in a range of about −3 mm to −7 mm, the average height of the curl is about −5.3125 mm, and an intermediate value is about −4.75 mm. Here, that the height of the curl has a negative value means that curl is applied in the upwardly convex shape, that is, in a reverse direction.

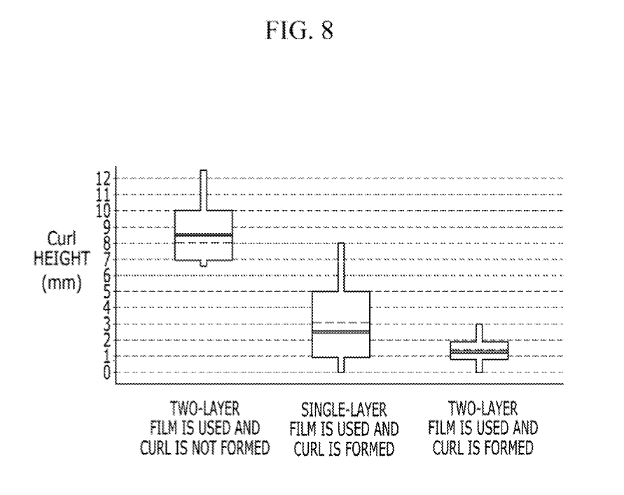

FIG. 8 is a graph measuring and illustrating the heights of the curl of the display device with the bottom protective layer attached to a display panel when the curl is not formed in the bottom protective layer of the organic light emitting diode (OLED) display according to an embodiment of the present invention, when the curl is formed in the single-layer bottom protective layer, and when the curl is formed in the two-layer bottom protective layer. That is, FIG. 8 illustrates results of measuring the heights of the curl of the display device in the case where the bottom protective layer of the three cases of FIG. 7 is attached to the display panel 101.

As shown in FIG. 8, when the bottom protective layer is formed of the two-layer film and is attached to the display panel 101 without applying curl, the height of the curl of the display device is distributed in a range of about 6.5 mm to 12.5 mm, the average height of the curl is about 8.5 mm, and an intermediate value is about 8 mm. In addition, when the bottom protective layer is made single and is attached to the display panel 101 with curl applied, the height of the display device is distributed in a range of about 0 mm to 8 mm, the average height of the curl is about 3.08929 mm, and an intermediate value is about 2.5 mm. In addition, when the bottom protective layer is formed of the two-layer film and is attached to the display panel 101 with curl applied, the height of the curl of the display device is distributed in a range of about 0 mm to 3 mm, the average height of the curl is about 1.375 mm, and an intermediate value is about 1.25 mm.

It may be noted from the experiment results of FIG. 8 that the bending phenomenon of the display device is relieved when the bottom protective layer is formed of the two-layer film and is attached to the display panel 101 with reverse curl applied. On the other hand, it is expected that the bending phenomenon of the display device may be relieved more when the bottom protective layer is formed of a multi-layer film consisting of no less than two layers while uniformly maintaining the entire thickness of the bottom protective layer and is attached to the display panel 101 with reverse curl applied.

In addition, tension may be adjusted to be applied when the reverse curl of the bottom protective layer is formed in accordance with the bending degree of the top protective layer and the display panel 101 so that the height of the curl of the bottom protective layer may be controlled and that the bottom protective layer may be attached to the top protective layer and the display panel 101.

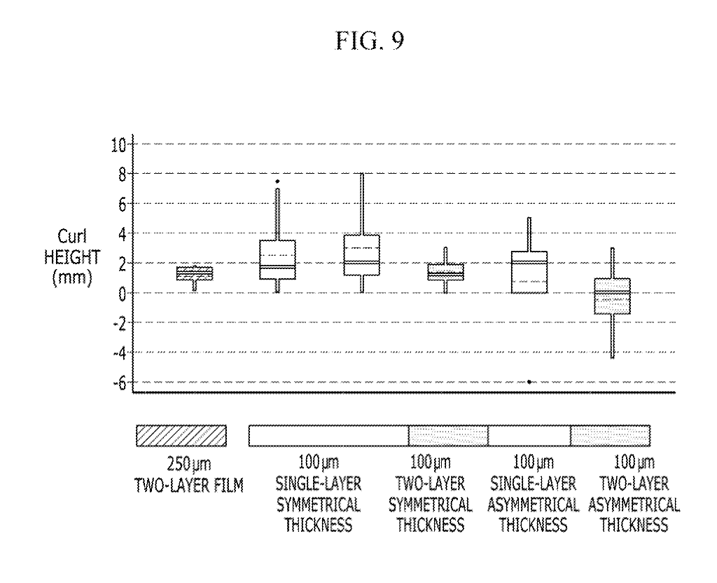

FIG. 9 is a graph measuring and illustrating the heights of the curl of a mother substrate when the bottom protective layer of the OLED display according to an embodiment of the present invention is attached to the mother substrate in accordance with thicknesses of the film that forms the bottom protective layer, whether the film is a single-layer film or a two-layer film, and whether the film is a symmetric film or an asymmetric film.

Referring to FIG. 9, when the bottom protective layer is formed of the two-layer film and is attached to the mother substrate using the second adhesive with a thickness of 250 μm, the heights of the curl of the mother substrate are determined to be about 0.1 mm to 0.8 mm. At this time, it is measured that the average height of the curl is about 1.15 mm and an intermediate value is about 1.35 mm.

In addition, when the bottom protective layer is formed of the single-layer film and is attached to the mother substrate using the second adhesive with a thickness of 100 μm, the heights of the curl of the mother substrate are determined to be about 0 mm to 7 mm. At this time, it is measured that the average height of the curl is about 2.45 mm and an intermediate value is about 1.75 mm. In addition, when an experiment is performed once more with the same condition, the heights of the curl of the mother substrate are determined to be about 0 mm to 8 mm. At this time, it is measured that the average height of the curl is about 3 mm and an intermediate value is about 2 mm.

In addition, when the bottom protective layer is formed of the two-layer film and is attached to the mother substrate using the second adhesive with the thickness of 100 μm, the heights of the curl of the mother substrate are determined to be about 0 mm to 3 mm. At this time, it is measured that the average height of the curl is about 1.375 mm and an intermediate value is about 1.25 mm.

In addition, when the bottom protective layer is formed of the single-layer film, the film and the adhesive are asymmetric, and the bottom protective layer is attached to the mother substrate using the second adhesive with the thickness of 100 μm, the heights of the curl of the mother substrate are determined to be about 0 mm to 5 mm. At this time, it is measured that the average height of the curl is about 0.75 mm and an intermediate value is about 2 mm.

In addition, when the bottom protective layer is formed of the two-layer film, the film and the adhesive are asymmetric, and the bottom protective layer is attached to the mother substrate using the second adhesive with the thickness of 100 μm, the heights of the curl of the mother substrate are determined to be about −4.5 mm to 3 mm. At this time, it is measured that the average height of the curl is about −0.468 mm and an intermediate value is about 0 mm.

From the experiment results of FIG. 9, it is noted that bending phenomenon of the mother substrate is relieved when the bottom protective layer is formed of the two-layer film and is attached to the display panel using the second adhesive with the thickness of 100 μm.

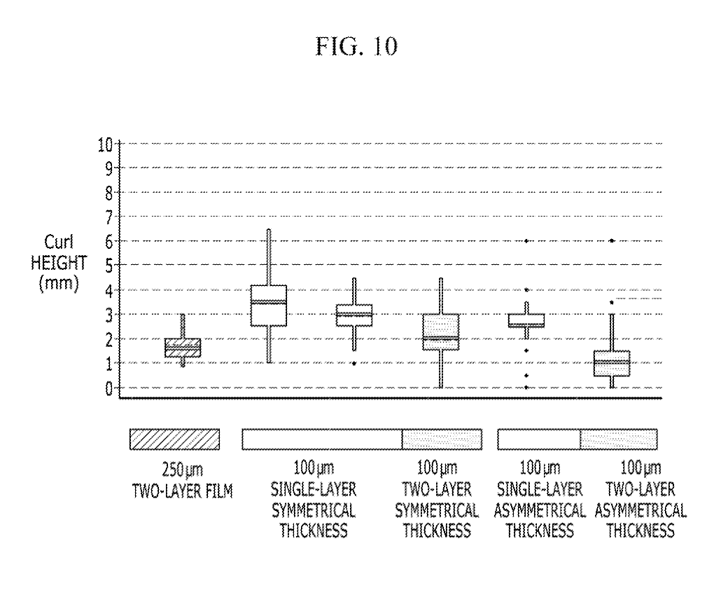

FIG. 10 is a graph measuring and illustrating the heights of the curl of a display device when the bottom protective layer of the OLED display according to an embodiment of the present invention is attached to the display device in accordance with thicknesses of the film that forms the bottom protective layer, whether the film is a single-layer film or a two-layer film, and whether the film is a symmetric film or an asymmetric film.

Referring to FIG. 10, when the bottom protective layer is formed of the two-layer film and is attached to the display device using the second adhesive with a thickness of 250 μm, the heights of the curl of the display device are determined to be about 1 mm to 3 mm. At this time, it is measured that the average height of the curl is about 1.7 mm and an intermediate value is about 1.6 mm.

In addition, when the bottom protective layer is formed of the single-layer film and is attached to the display device using the second adhesive with a thickness of 100 μm, the heights of the curl of the display device are determined to be about 1 mm to 6.5 mm. At this time, it is measured that the average height of the curl is about 3.4 mm and an intermediate value is about 3.5 mm. In addition, when an experiment is performed once more with the same condition, the heights of the curl of the display device are determined to be about 1.5 mm to 4.5 mm. At this time, it is measured that the average height of the curl is about 2.95 mm and an intermediate value is about 3 mm.

In addition, when the bottom protective layer is formed of the two-layer film and is attached to the display device using the second adhesive with the thickness of 100 μm, the heights of the curl of the display device are determined to be about 0 mm to 4.5 mm. At this time, it is measured that the average height of the curl is about 2.1 mm and an intermediate value is about 2 mm.

In addition, when the bottom protective layer is formed of the single-layer film, the film and the adhesive are asymmetric, and the bottom protective layer is attached to the display device using the second adhesive with the thickness of 100 μm, the heights of the curl of the display device are determined to be about 2 mm to 3.5 mm. At this time, it is measured that the average height of the curl is about 2.57 mm and an intermediate value is about 2.5 mm.

In addition, when the bottom protective layer is formed of the two-layer film, the film and the adhesive are asymmetric, and the bottom protective layer is attached to the display device using the second adhesive with the thickness of 100 μm, the heights of the curl of the display device are determined to be about 0 mm to 3 mm. At this time, it is measured that the average height of the curl is about 1.05 mm and an intermediate value is about 1 mm.

From the experiment results of FIG. 10, it is noted that bending phenomenon of the display device is relieved when the bottom protective layer is formed of the two-layer film and is attached to the display panel using the second adhesive with the thickness of 100 μm.

As described above, in the organic light emitting diode (OLED) display according to the embodiments of the present invention and the method of manufacturing the same, the bottom protective layer of the display panel is formed of the two-layer film and is attached to the display panel with the reverse curl applied in the opposite direction to the bending direction of the display panel so that the bending phenomenon of the display device may be relieved.

In addition, the bottom protective layer may be formed of the asymmetric two-layer film to a thickness of about 100μ to relieve the bending phenomenon of the display device.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display device, comprising:
a display panel including a flexible substrate and a thin film encapsulation (TFE), the TFE covering and protecting an organic light emitting element formed on the flexible substrate;
a first protective film formed on a surface of the TFE;
a second protective film formed on a surface of the flexible substrate;
a first adhesive interposed between the TFE and the first protective film;
a second adhesive interposed between the flexible substrate and the second protective film;
a third protective film formed on the second protective film; and
a third adhesive interposed between the second protective film and the third protective film.

2. The organic light emitting diode (OLED) display device of claim 1, wherein the second adhesive and the third adhesive are formed of a same material.

3. The organic light emitting diode (OLED) display device of claim 1, wherein the first, second, and third protective films are formed of a same material.

4. The organic light emitting diode (OLED) display device of claim 1, wherein the first adhesive has a thickness of about 70 μm to 80 μm.

5. The organic light emitting diode (OLED) display device of claim 1, wherein each of the second adhesive and the third adhesive has a thickness of about 20 μm to 30 μm.

6. The organic light emitting diode (OLED) display device of claim 1, wherein the flexible substrate is formed of a plastic material.

7. The organic light emitting diode (OLED) display device of claim 1, wherein the first, second, and third protective films are formed of a flexible plastic material.

8. The organic light emitting diode (OLED) display device of claim 1, wherein the first protective film has a thickness of about 70 μm to 80 μm.

9. The organic light emitting diode (OLED) display device of claim 1, wherein each of the second protective film and the third protective film has a thickness of about 20 μm to 30 μm.

10. The organic light emitting diode (OLED) display device of claim 1, further comprising:
a fourth protective film formed on the first protective film; and
a fourth adhesive interposed between the first protective film and the fourth protective film,
wherein the first adhesive and the fourth adhesive are formed of a same material.

11. The organic light emitting diode (OLED) display device of claim 10, wherein the first through fourth protective films are formed of a same material.

12. The organic light emitting diode (OLED) display device of claim 10, wherein the fourth adhesive has a thickness of about 5 μm to 15 μm.

13. The organic light emitting diode (OLED) display of claim 10, wherein at least one of the first through fourth protective films is polarizing film.

14. The organic light emitting diode (OLED) display device of claim 10, wherein the fourth protective film has a thickness of about 20 μm to 30 μm.

15. The organic light emitting diode (OLED) display device of claim 1, wherein a total thickness of the second adhesive, the second protective film, the third adhesive, and the third protective film is about 90 μm to 110 μm.

16. The organic light emitting diode (OLED) display device of claim 15, wherein:
the second protective film has a thickness of about 45 μm to 50 μm, and
the third protective film has a thickness of about 20 μm to 30 μm.
